(19) United States
(12) Patent Application Publication
(10) Pub. No.: US 2005/0127484 A1
(43) Pub. Date: Jun. 16, 2005

(54) Die extender for protecting an integrated circuit die on a flip chip package

(75) Inventor: Kendall Scott Wills, Sugarland, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 10/737,682

(22) Filed: Dec. 16, 2003

(51) Int. Cl. H01L 23/02

(52) U.S. Cl. 257/678

(57) ABSTRACT

A semiconductor package is provided including a substrate, an integrated circuit die, and a die extender disposed on the substrate around the die. The die extender protects the die from damage. The die extender is typically at least as thick as the die. In addition, the die extender may frame the die. The thickness of the die extender may be such that a heat sink device applied to the package contacts the die extender prior to contacting the die. The die extender may or may not be in contact with the die.

### FIELD OF THE INVENTION

This application relates generally to integrated circuit (IC) packaging and in particular to a die extender for protecting an IC die on a flip chip package during handling.

### BACKGROUND OF THE INVENTION

Integrated circuits are fabricated on the surface of a semiconductor wafer in layers and later singulated into individual semiconductor devices, or “dies.” Many fabrication processes are repeated numerous times, constructing layer after layer until fabrication is complete. Metal layers, which typically increase in number as device complexity increases, include patterns of conductive material that are vertically insulated from one another by alternating layers of insulating material. Conductive traces are also separated within each layer by an insulating, or dielectric, material. Vertical, conductive tunnels called “vias” typically pass through insulating layers to form conductive pathways between adjacent conductive patterns. Since the material of a semiconductor wafer—commonly silicon—tends to be relatively fragile and brittle, dies are often assembled into protective housings, or “packages,” before they are interconnected with a printed circuit board (PCB).

Flip-chip interconnect technology supports “area array interconnection,” a technology in which the die (or “chip”) can be mechanically and electrically connected to a substrate or board through an array of solder bumps on the active face of the die. As the entire active face of the die (and not just the periphery) can be used for interconnections, this technique increases the number of connections that can be made for a given die size. The die is affixed to the substrate facedown (or “flipped”) by slightly melting the solder bumps in an oven reflow process, attaching them to the substrate. The solder bump area is often reinforced by introducing an epoxy underfill between the die and the substrate in order to improve solder joint reliability. Electrical performance can also be improved by reducing inductance and capacitance, as a result of the reduced distance between the active surface of the die and the underlying board over non-flip-chip configurations.

In one form of flip chip package a lid is attached to protect the backside of the die. FIG. 1 illustrates a perspective view of an example of a semiconductor package 10 of the prior art. The package 10 includes the substrate 12, the IC die 14 attached in a flip chip position, and a lid 16 attached with a lid adhesive 18. The lid 16 acts as a protective covering for the die 14, providing mechanical stability and permitting easier handling of the package 10. Several issues are associated with employment of a lid 16 in a flip chip package 10. A heat sink is typically applied to the lid 16 in order to aid cooling of the IC die 14. The lid 16 limits heat transfer from the die 14 to the heat sink. The lid 16 is also expensive and the process of attaching the lid requires extra processing and temperature cycling steps. In addition, when the package 10 is put through a temp cycle (TC) stress test, the adhesives employed to hold the lid 16 in combination with the rigidity of the lid 16 cause stresses on the die 14, which reduce the die's 14 reliability.

In another form of flip chip package, the package does not have a lid, or is lidless. In the case of a lidless package, a heat sink may be applied directly to the surface of the die 210. The heat sink may contact the die 210 such that the surface of the heat sink is not flush or perfectly planar with the surface of the die 210. Such uneven contact may cause cracks in the IC 210 or damage the edge of the die 210 if the heat sink makes inexact contact with either the surface of the die 210 or a die 210 edge. Such damage may harm the integrity of the electrical connections of the package 200. Thus, a need exists for an improved flip chip package that reduces stresses on and risk of physical damage to the IC die, while improving heat transfer during heat sinking.

### SUMMARY OF THE INVENTION

In an embodiment, a semiconductor package is provided including a substrate, an integrated circuit die, and a die extender disposed on the substrate around the die. In another embodiment, the die extender protects the die from damage. In another embodiment, the die extender frames the die. In another embodiment, the die extender is at least as thick as the die. In another embodiment, the die extender is of a thickness such that a heat sink device applied to the package contacts the die extender prior to contacting the die. In an embodiment, the die extender is in contact with the die. In another embodiment, the die extender is not in contact with the die.

In an embodiment, a method is provided including attaching an IC die to a substrate and disposing a die extender on the substrate around the perimeter of the die wherein the die extender protects the die. In another embodiment, the method provided includes applying a heat sink compound or a metal layer to the die wherein the heat sink compound or metal layer further protects the die and provides thermal contact between the die and a heat sink. In another embodiment, the heat sink compound or metal layer may be applied via sintering, sputtering, laser processing, or placing of a pre-formed piece.

### BRIEF DESCRIPTION OF THE DRAWINGS

FIG. 1 illustrates a cross-sectional view of a flip chip package of the prior art.

FIG. 2 illustrates a cross-sectional view of an embodiment of a lidless flip chip package including a die extender wherein the die extender is planar with the surface of the die.

FIG. 3 illustrates a cross-sectional view of an embodiment of a lidless flip chip package including a die extender comprised of two components wherein one component acts as an adhesive.

FIG. 4 illustrates a cross-sectional view of an embodiment of a lidless flip chip package including a die extender comprised of two components wherein one component is inserted in the second component.

FIG. 5 illustrates a cross-sectional view of an embodiment of a lidless flip chip package including a die extender wherein the die extender is not planar with the surface of the die.

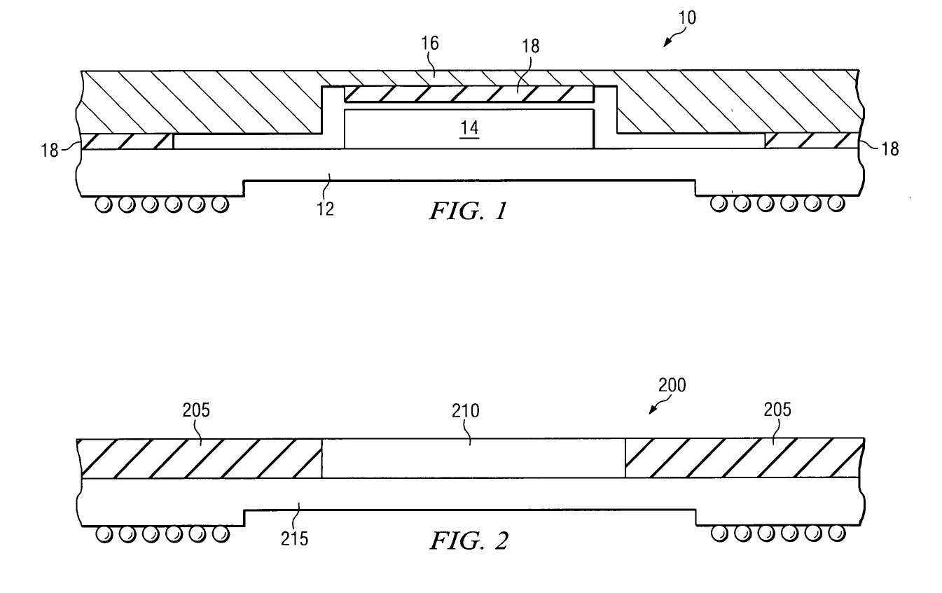

### NOTATION AND NOMENCLATURE

Certain terms are used throughout the following description and claims to refer to particular.system components. As one skilled in the art will appreciate, companies may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . ”.

The term “integrated circuit” or “IC” refers to a set of electronic components and their interconnections (internal electrical circuit elements, collectively) that are patterned on the surface of a microchip. The term “semiconductor device” refers generically to an integrated circuit (IC). The term “die” (“dies” for plural) refers generically to an integrated circuit, in various stages of completion, including the underlying semiconductor substrate and all circuitry patterned thereon. The term “flip chip” refers to a bumped die, which is designed for a face-down direct interconnection with an underlying electrical component through a C4 or bumped connection.

The terms “semiconductor package,” “integrated circuit package,” “IC package,” or “package” refer generically to a die mounted within a package, as well as all package constituent components. To the extent that any term is not specially defined in this specification, the intent is that the term is to be given its plain and ordinary meaning.

### DETAILED DESCRIPTION OF EMBODIMENTS

FIG. 2 illustrates an embodiment of a semiconductor package 200 incorporating a die extender 205. The die extender 205 frames an integrated circuit die 210 and, like the die 210, the die extender 205 is affixed to the package substrate 215. For purposes of describing FIGS. 2 through 5, unless otherwise stated, the “surface” or “top surface” of the die 210 or die extender 205 refers to the surface opposite the substrate 215. In addition, the terms “thick” or “thickness” when used to describe the die 210 or die extender 205 refer to the distance from the surface of the die 210 or die extender 205 in contact with the substrate 215, to the surface of the die 210 or die extender 205 opposite the substrate 215. Further, the terms “frames” or “framing,” when used to describe the position of the die extender 205 relative to the die 210, may refer to a continuous or intermittent die extender 205, and may refer to a die extender 205 that is or is not in contact with the die. In an embodiment, the IC package 200 is a flip chip package and the die 210 is attached in a flip chip position. In another embodiment, the package 200 is lidless. In another embodiment, the top surface of the die extender 205 is substantially planar with the top surface of the die 210. In another embodiment, the die extender 205 is at least as thick as the die 210. In another embodiment, the die extender 205 is thicker than the die 210.

By framing the die 210 and effectively extending the top surface of the die 210, the die extender 205 reduces the risk of damage caused by operation of a heat sink on the die 210, and acts as a shield for and relieves stresses on the die 210. In an embodiment, the die extender acts as a protective ring around the die. In another embodiment, the outermost perimeter of the die extender 205 is substantially aligned with the perimeter of the substrate 215. In another embodiment, the outermost perimeter of the die extender 205 is within the outer perimeter of the substrate 215. In another embodiment, the die extender 205 is in contact with the die 210. In another embodiment, the innermost perimeter of the die extender 205 contacts and conforms to the shape of the outside perimeter of the die 210. In another embodiment, the die extender 205 is not in contact with the die 210.

The die extender 205 generally occupies some or all of the surface area of the substrate 215 that is not occupied by the die 210. In the embodiment illustrated by FIG. 2, the die extender 205 is made up of a continuous formation on the surface of the substrate 215 that frames the die 210. In another embodiment, the die extender 205 includes two or more consistently or intermittently spaced formations on the surface of the substrate 215. As an example, the die extender may be a continuous formation that frames the die and possesses a footprint or breadth such that it occupies only a small percentage of the surface area of the substrate, forming a relatively thin protective ring around the die. In another example, the die extender may be a series of consistently or intermittently spaced columns of a variety of breadths and geometries that occupy the surface of the substrate.

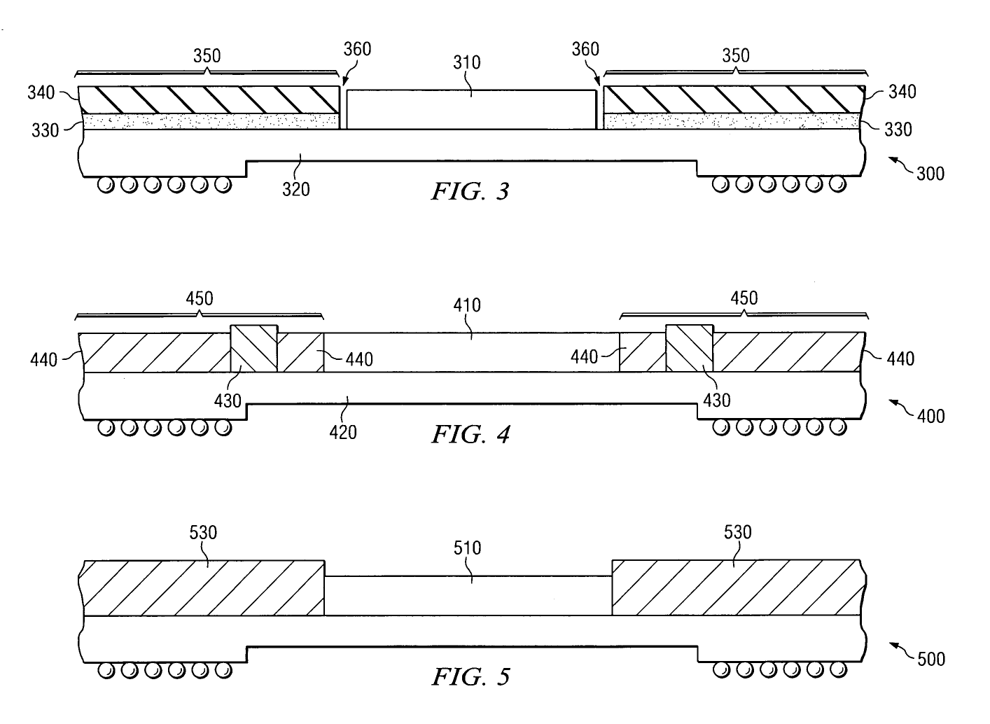

FIG. 3 illustrates a cross-sectional view of an embodiment of a semiconductor package 300 including a die extender 350. In this embodiment, the die extender 350 is a protective ring that frames the IC die 310 and occupies most of the surface area of the substrate 320 not occupied by the die 310. The die extender 350 is not in contact with the IC die 310, as evidenced by the gap 360 shown between the die extender 350 and the die 310. In an embodiment, the die extender 350 is made up of two or more components. In another embodiment, the die extender 350 includes a first layer 330 disposed on the substrate 320 and a second layer 340 disposed on the first layer 330, whereby the first layer 330 attaches the second layer 340 to the substrate 320. In another embodiment, the first layer 330 comprises an adhesive or glue.

The surface of the second layer 340 opposite the first layer 330 may be substantially planar with the top surface of the die 310, or may rise above the top surface of the die 310 such that a heat sink (not shown) would first contact the surface of the second layer 340 before making contact with the die 310. The second layer 340 may be composed of a less rigid and compressible material such that a heat sink first contacting the second layer 340 may compress the second layer 340 before contacting the die 310. Such a design may protect both the top surface of the die 310 and the die 310 edges by absorbing part of the force associated with the employment of a heat sink to the die 310. The extender 350 may protect the die 310 edges and absorb the force of a heat sink as it is applied to the die, regardless of whether the die extender 350 is in contact with the die 310.

FIG. 4 illustrates a cross-sectional view of an embodiment of a semiconductor package 400. The package 400 includes a die 410 attached to a package substrate 420. A die extender 450 includes a first component 440 disposed on the substrate 420 and a second component 430 that may be embedded in the first component 440. The first 440 and second 430 components are typically composed of different materials as provided herein. The second component 430 may or may not be disposed directly on the substrate 420. In an embodiment, both the first and second components 440, 430 are in contact with the substrate 420 and the first component 440 occupies a greater percentage of the surface area of the substrate 420 than the second component 430. In another embodiment, both the first 440 and second 430 components are in contact with the substrate 420 and the second component 430 occupies a greater percentage of the surface of the substrate 420 than the first component 440. In another embodiment, both the first 440 and second 430 components are in contact with the substrate 420 and occupy substantially equal percentages of the surface of the substrate 420.

A die extender 450 comprising more than one component may be designed such that it protects the edges of the die 410, and such that a heat sink applied to the package 400 first contacts one component made of a more compressible material, and then contacts the second component made of a less compressible material, or vice versa. In an embodiment, the second component 430 comprises a thickness such that a heat sink applied to the package 400 would contact the second component 430 prior to contacting the first component 440 and/or the die 410. In another embodiment, the first component 440 comprises a thickness such that a heat sink applied to the package 400 would contact the first component 440 prior to contacting the second component 430 and the die 410. In another embodiment, the first component 440 and second component 430 are designed such that the surface of the second component 430 is substantially planar with the surface of the first component 440. In another embodiment, the first component 440, the second component 430, or both may be substantially planar with the surface of the die 410.

In one example of a die extender illustrated by the embodiment of FIG. 4, a first component 440 may be more rigid than the second component 430. A heat sink applied to the package 400 would first contact the second component 430. The material and design of the second component 430 may be such that the pressure associated with applying the heat sink compresses the second component 430. In this way the second component 430 acts to provide a cushion as the heat sink is applied to the die. The surface of the first component 440, may be either substantially planar with the corresponding surface of the die 410, or between the surface of the die 410 and the surface of the second component 430. The level of the surface of the first component 440 may be set such that it absorbs some of the pressure stresses associated with applying the heat sink to the die 410, while also permitting sufficient contact between the heat sink and die 410 for effective heat sinking to occur. In addition, the first component 440 may contribute to leveling the heat sink so that it makes flush contact with the die 410. Thus, the first component 440 and second component may together provide a cushion and stabilizing effect for the package 400 and die 410 as a heat sink is applied.

FIG. 5 illustrates a cross-sectional view of an embodiment of a semiconductor package 500 as provided herein. The package 500 includes a die 510 and a die extender 530. In an embodiment, the die extender 530 is at least as thick as the die 510. As illustrated by the embodiment of FIG. 5, the die extender 530 may be thicker than the die 510. In an embodiment, the die extender material may include a foaming agent so that a heat sink may compress the die extender 530 in order to make sufficient contact with the die. The foaming agent may be a separate layer or integral to the die extender material. The foaming agent may enhance the ability of the heat sink to compress the die extender 530 in order to make sufficient contact with the die 510. The die extender 530 may be as thick as or thicker than the die 510 as long as effective contact may be made between the die 510 and a heat sink.

In an embodiment, a heat sink compound is applied between the die 510 and a heat sink. Appropriate heat sink compounds are known in the art. Examples include those supplied by Herbach and Rademan of Moorestown, N.J., and those supplied by All Electronics Corporation of Van Nuys, Calif. An example is a zinc oxide filled silicone that meets military specification (Mil-Spec) C-4713. In an embodiment, a metal layer is placed between the die 510 and a heat sink. A heat sink compound, metal layer, or a combination of a heat sink compound and metal layer may improve thermal contact between a heat sink and the die 510 and also help prevent the heat sink from damaging the die. Particles or contaminants trapped between a heat sink and the die 510 may be compacted against the die 510 by the heat sink causing damage to and cracks in the die 510. A heat sink compound, metal layer, or a combination of a heat sink compound and metal layer is typically compressible and acts as a cushion to absorb such particles and contaminants and protect the die 510 from damage while also providing effective thermal contact between the die 510 and heat sink. In an embodiment, the metal layer is composed of a soft metal. In another embodiment, the metal layer may be comprised of aluminum, indium, copper, silver, gold, tungsten, titanium, iron, chrome, nickel or combinations thereof. In another embodiment, the metal layer may be a discontinuous layer or mesh. A soft heat sink compound or metal layer such as aluminum is designed to be supple enough to compensate for roughness, particles, and/or irregularities between the surface of a heat sink and the surface of the die 510 as the heat sink is pressed against the package 500. Such softness promotes flush physical and effective thermal contact between the die 510 and heat sink.

In an embodiment, a method is provided including attaching an IC die to a package substrate and disposing a die extender around the perimeter of the die on the substrate, where the die extender frames the die and protects the die during handling. In another embodiment, a metal layer or heat sink compound is employed between a heat sink and an IC die. The metal layer or heat sink compound may be applied to a semiconductor package by any means known in the art. In embodiments, the metal layer is applied via sintering, sputtering, laser processing, or placing of a pre-formed metal piece. The metal layer may be removable after contact with a heat sink. The die extender is designed to provide protection to the IC die during various forms of handling of an IC package. Such handling may be any step known in the art of semiconductor manufacturing to result in mechanically contacting the die. Examples of such handling include clamping, testing, temperature cycling, electrically connecting, applying a heat sink compound, and applying a heat sink. Applying a heat sink may include direct contact with the die, or a heat sink compound or metal layer may be placed between the heat sink and die.

In another embodiment, a method of modifying a semiconductor package includes disposing a die extender on a package substrate such that the die extender frames and protects an IC die on the substrate. In embodiments, the die extender is at least as thick as the die and disposed on the substrate around the perimeter of the die. A die extender may be applied to a semiconductor package via any means known in the art. In an embodiment, the die extender may be applied by pouring into a cast, silk screening or screen printing, spraying, injection molding, painting, dispensing from a syringe, placing of a pre-formed piece, or combinations thereof. The die extender may be formed of various materials. Any material that may be formed to act as a die extender to prevent damage to an IC die may be appropriate. The rigidity of the die extender material may vary according to the type of material used and its compressibility. In embodiments, the die extender material comprises an epoxy component, a foaming agent, a thermal plastic, or combinations thereof. Appropriate foaming agents are known in the art, such as, for example, those supplied by Clariant Corporation of Holden, Mass. In another embodiment, the one or more die extender components are selected so that they possess coefficients of thermal expansion (CTE) such that no de-lamination occurs.

While embodiments of the invention have been shown and described, modifications thereof can be made by one skilled in the art without departing from the spirit and teachings of the invention. The embodiments described herein are exemplary only, and are not intended to be limiting. Equivalent techniques and ingredients may be substituted for those shown, and other changes can be made within the scope of the present invention as defined by the appended claims. Many variations and modifications of the invention disclosed herein are possible and are within the scope of the invention. Accordingly, the scope of protection is not limited by the description set out above, but is only limited by the claims which follow, that scope including all equivalents of the subject matter of the claims.

1. A semiconductor package comprising:
a substrate;
an integrated circuit (IC) die attached to said substrate; and
a die extender disposed on said substrate;
wherein said die extender frames said die and is at least as thick as said die.

2. The package of claim 1 wherein said die extender prevents damage to said die.

3. The package of claim 1 wherein said package is a flip chip package.

4. The package of claim 1 wherein said package is lidless.

5. The package of claim 1 wherein said die extender comprises a top surface that is substantially planar with a top surface of said die.

6. The package of claim 1 wherein said die extender is thicker than said die.

7. The package of claim 1 wherein said die extender comprises a thickness such that a heat sink device contacts said die extender prior to contacting said die.

8. The package of claim 1 wherein an outermost perimeter of the die extender is substantially aligned with an outer perimeter of the substrate.

9. The package of claim 1 wherein an outermost perimeter of said die extender is within an outer perimeter of the substrate.

10. The package of claim ` wherein said die extender is in contact with said die.

11. The package of claim 1 wherein said die extender is not in contact with said die.

12. The package of claim 1 wherein said die extender comprises one or more components.

13. The package of claim 1 wherein said die extender comprises at least two components.

14. The package of claim 1 wherein said die extender comprises a first component and a second component wherein said second component comprises a thickness such that a heat sink contacts said second component prior to contacting said first component and said die.

15. The package of claim 1 wherein said die extender comprises a first component and a second component wherein said second component is substantially planar with the surface of said first component.

16. The package of claim 1 wherein said die extender comprises two or more consistently or intermittently spaced formations on the surface of the IC package.

17. The package of claim 1 wherein said die extender comprises a first layer and a second layer wherein said second layer is attached to said substrate by said first layer.

18. The package of claim 1 further comprising a heat sink compound between said die extender and a heat sink.

19. The package of claim 1 further comprising a metal layer between said die extender and a heat sink.

20. The package of claim 19 wherein said metal layer comprises aluminum, indium, copper, silver, gold, tungsten, titanium, iron, chrome, nickel or combinations thereof.

21. A method comprising:
attaching an IC die to a substrate; and
disposing a die extender on said substrate around the perimeter of said die;
wherein said die extender, having a surface distant from the substrate and substantially coplanar with a surface of said IC die, protects said die.

22. The method of claim 21 further comprising applying a heat sink to said die to protect said die and to provide thermal contact between said die and the heat sink.

23. The method of claim 22 wherein said applying comprises sintering, sputtering, laser processing, or placing of a pre-formed piece.

24. A semiconductor package made according to a method comprising disposing a die extender on a substrate around the perimeter of an IC die wherein said die extender, having a surface distant from the substrate and substantially coplanar with a surface of the IC die, protects said die.

25. The package of claim 24 wherein said die extender is at least as thick as said die.

26. The package of claim 24 wherein disposing comprises pouring into a cast, silk screening, screen printing, spraying, injection molding, painting, dispensing from a syringe, placing of a pre-formed piece, or combinations thereof.

27. The package of claim 24 wherein said die extender comprises at least two components and wherein disposing comprises one or more application steps.

28. A semiconductor package comprising:
a substrate;
an IC die disposed on said substrate; and
a means for preventing structural damage to said die during handling.

29. The package of claim 28 wherein said means is at least as thick as said die.

30. The package of claim 28 further comprising a heat sink compound or a metal layer applied to said die wherein said heat sink compound or metal layer further protects said die and is adapted to provide thermal contact between said die and a heat sink.

31. The package of claim 28 wherein a beat sink applied to said package contacts said means prior to contacting said die.
